(19) United States
(12) Patent Application Publication
(10) Pub. No.: US 2025/0343027 A1
(43) Pub. Date: Nov. 6, 2025

(54) PLASMA-PROCESSING APPARATUS AND PLASMA-PROCESSING METHOD

(71) Applicant: Tokyo Electron Limited, Tokyo (JP)

(72) Inventors: Ryuta HIGUCHI, Miyagi (JP); Toshiki NAKAJIMA, Miyagi (JP)

(73) Assignee: Tokyo Electron Limited, Tokyo (JP)

(21) Appl. No.: 19/265,822

(22) Filed: Jul. 10, 2025

Related U.S. Application Data
(63) Continuation of application No. PCT/JP2024/000187, filed on Jan. 9, 2024.

(30) Foreign Application Priority Data
Jan. 18, 2023 (JP) 2023-005664

(51) Int. Cl. H01J 37/32

(52) U.S. Cl. CPC H01J 37/32165; H01J 37/3211; H01J 37/32174; H01J 37/3299

(57) ABSTRACT

The plasma-processing apparatus includes a chamber, a substrate support, an antenna, an RF generator, and a controller. The RF generator is configured to generate an RF signal. The controller is configured to control the RF generator to set, in a first period, a power level of a first frequency component of the RF signal to a power level greater than a power level of a second frequency component of the RF signal in order to ignite plasma in the chamber, and set, in a second period, the power level of the second frequency component to a power level greater than the power level of the first frequency component in order to maintain the ignited plasma.

### CROSS-REFERENCE TO RELATED APPLICATIONS

This application is a continuation application of PCT Application No. PCT/JP2024/000187, filed on Jan. 9, 2024, which claims the benefit of priority from Japanese Patent Application No. 2023-005664, filed on Jan. 18, 2023. The entire contents of the above listed PCT and priority applications are incorporated herein by reference.

### BACKGROUND

### Field

Exemplary embodiments of the present disclosure relate to a plasma-processing apparatus and a plasma-processing method.

### Description of the Related Art

A plasma-processing apparatus is used in plasma processing to be performed on a substrate. The plasma-processing apparatus ignites plasma in a chamber by supplying a radio frequency signal. Japanese Unexamined Patent Publication No. 2021-64482 discloses a plasma-processing apparatus that modulates at least one of a power level of the radio frequency signal and a frequency of the radio frequency signal.

### SUMMARY

In one exemplary embodiment, there is provided a plasma-processing apparatus. The plasma-processing apparatus includes a chamber, a substrate support, an antenna, an RF generator, and a controller. The substrate support is in the chamber. The antenna is above the substrate support. The RF generator is electrically connected to the antenna. The RF generator is configured to generate an RF signal. The RF signal includes one or both of a first frequency component and a second frequency component. The first frequency component is a frequency component for igniting plasma in the chamber. The second frequency component is a frequency component for maintaining the ignited plasma. The first frequency component has a first frequency. The second frequency component has a second frequency different from the first frequency. The second frequency is a matching frequency. The controller is configured to control the RF generator to set, in a first period, a power level of a first frequency component of the RF signal to a power level greater than a power level of a second frequency component of the RF signal in order to ignite plasma in the chamber, and set, in a second period, the power level of the second frequency component to a power level greater than the power level of the first frequency component in order to maintain the ignited plasma.

### BRIEF DESCRIPTION OF THE DRAWINGS

FIG. 1 is a diagram for describing a configuration example of a plasma processing system.

FIG. 2 is a diagram for describing a configuration example of an inductively coupled plasma-processing apparatus.

FIG. 3 is a diagram showing a configuration of a power supply system and a control system in the plasma-processing apparatus according to one exemplary embodiment.

FIG. 4 is a diagram showing a configuration of a first RF generator of the plasma-processing apparatus according to one exemplary embodiment.

FIG. 5 is a diagram showing a change in time of a plurality of frequency components of a source RF signal generated by the first RF generator in one exemplary embodiment.

FIG. 6 is a diagram showing a change in time of a plurality of frequency components of a source RF signal generated by the first RF generator in another exemplary embodiment.

FIG. 7 is a diagram showing a change in time of a plurality of frequency components of a source RF signal generated by the first RF generator in still another exemplary embodiment.

FIG. 8 is a flowchart of a plasma-processing method according to one exemplary embodiment.

FIG. 9 is a flowchart of a plasma-processing method according to another exemplary embodiment.

### DETAILED DESCRIPTION

Hereinafter, various exemplary embodiments will be described in detail with reference to the drawings. In the drawing, the same or equivalent portions are denoted by the same reference signs.

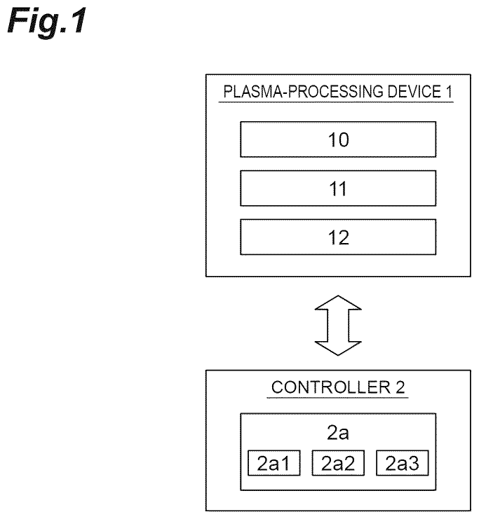

FIG. 1 is a diagram for describing a configuration example of a plasma processing system. In one embodiment, a plasma processing system includes a plasma-processing apparatus 1 and a controller 2. The plasma processing system is an example of a substrate processing system, and the plasma-processing apparatus 1 is an example of a substrate processing apparatus. The plasma-processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one process gas into the plasma processing space and at least one gas exhaust port for exhausting gases from the plasma processing space. The gas supply port is connected to a gas supply 20 described below and the gas exhaust port is connected to an exhaust system 40 described below. The substrate support 11 is disposed in the plasma processing space and has a substrate support surface for supporting the substrate.

The plasma generator 12 is configured to generate plasma from the at least one process gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), or a surface wave plasma (SWP), or the like. In addition, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 100 kHz to 150 MHz.

The controller 2 processes computer-executable instructions for causing the plasma-processing apparatus 1 to execute various steps described in the present disclosure. The controller 2 may be configured to control each element of the plasma-processing apparatus 1 to execute various steps described herein. In one embodiment, the controller 2 may be partially or entirely incorporated into the plasma-processing apparatus 1. The controller 2 may include a processor 2a1, a storage 2a2, and a communication interface 2a3. The controller 2 is realized by, for example, a computer 2a. The processor 2a1 can be configured to read out a program from the storage 2a2 and execute the read out program to perform various control operations. This program may be stored in the storage 2a2 in advance, or may be acquired via the medium when necessary. The acquired program is stored in the storage 2a2, and is read out from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma-processing apparatus 1 via a communication line such as a local area network (LAN).

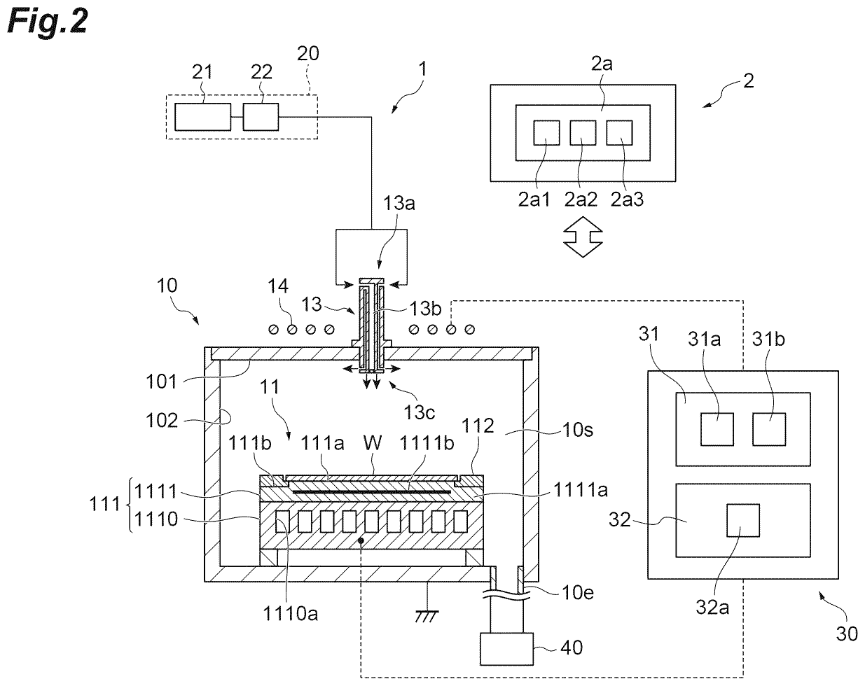

In the following, a configuration example of an inductively coupled plasma-processing apparatus, which is an example of the plasma-processing apparatus 1, will be described. FIG. 2 is a diagram for describing a configuration example of an inductively coupled plasma-processing apparatus.

The inductively coupled plasma-processing apparatus 1 includes the plasma processing chamber 10, the gas supply 20, a power supply 30, and an exhaust system 40. The plasma processing chamber 10 includes a dielectric window 101. In addition, the plasma-processing apparatus 1 includes a substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101).

The plasma processing chamber 10 has a plasma processing space 10s that is defined by the dielectric window 101, a side wall 102 of the plasma processing chamber 10, and the substrate support 11. The plasma processing chamber 10 is grounded.

The substrate support 11 includes a body 111 and a ring assembly 112. The body 111 has a central region 111a for supporting the substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 to surround the substrate W on the central region 111a of the body 111. Thus, the central region 111a is also referred to as a substrate support surface for supporting the substrate W, while the annular region 111b is also referred to as a ring support surface for supporting the ring assembly 112.

In one embodiment, the body 111 includes a base 1110 and an electrostatic chuck 1111. The base 1110 includes a conductive member.

The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. In addition, other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 described below may be disposed in the ceramic member 1111a. In this case, at least one RF/DC electrode functions as the bias electrode. The conductive member of the base 1110 and at least one RF/DC electrode may function as a plurality of bias electrodes. In addition, the electrostatic electrode 1111b may function as the bias electrode. Therefore, the substrate support 11 includes at least one bias electrode.

The ring assembly 112 includes one or a plurality of annular members. In one embodiment, the one or more annular members include one or a plurality of edge rings and at least one cover ring. The edge ring is formed of a conductive material or an insulating material, and the cover ring is formed of an insulating material.

In addition, the substrate support 11 may include a temperature adjusting module that is configured to adjust at least one of the electrostatic chuck 1111, the ring assembly 112, and the substrate to a target temperature. The temperature adjusting module may include a heater, a heat transfer medium, a flow path 1110a, or any combination thereof. A heat transfer fluid, such as brine or gas, flows into the flow path 1110a. In one embodiment, the flow path 1110a is formed in the base 1110, and one or a plurality of heaters are disposed in the ceramic member 1111a of the electrostatic chuck 1111. In addition, the substrate support 11 may further include a heat transfer gas supply configured to supply a heat transfer gas to a gap between a back surface of the substrate W and the central region 111a.

The gas introduction unit is configured to introduce at least one process gas from the gas supply 20 into the plasma processing space 10s. In one embodiment, the gas introduction unit includes a center gas injector (CGI) 13. The center gas injector 13 is disposed above the substrate support 11 and is attached to a central opening formed in the dielectric window 101. The center gas injector 13 has at least one gas supply port 13a, at least one gas flow path 13b, and at least one gas introduction port 13c. The process gas supplied to the gas supply port 13a passes through the gas flow path 13b and is introduced into the plasma processing space 10s from the gas introduction port 13c. The gas introduction unit may include one or a plurality of side gas injectors (SGIs) attached to one or a plurality of openings formed in the side wall 102, in addition to or instead of the center gas injector 13.

The gas supply 20 may include at least one gas source 21 and at least one flow rate control device 22. In one embodiment, the gas supply 20 is configured to supply at least one process gas from the respective corresponding gas source 21 through the respective corresponding flow rate control device 22 to the gas introduction unit. Each flow rate control device 22 may include, for example, a mass flow controller or a pressure-controlled flow rate control device. Further, the gas supply 20 may include at least one flow rate modulation device that modulates or pulses the flow rate of the at least one process gas.

The power supply 30 includes an RF power supply 31, which is coupled to the plasma processing chamber 10 via at least one impedance matching circuit. The RF power supply 31 is configured to supply at least one RF signal (RF power) to at least one bias electrode and the antenna 14. As a result, plasma is formed from at least one process gas supplied to the plasma processing space 10s. Therefore, the RF power supply 31 can function as at least a part of the plasma generator 12. In addition, by supplying the bias RF signal to at least one bias electrode, a bias potential is generated on the substrate W, and ion in the formed plasma can be drawn into the substrate W.

In one embodiment, the RF power supply 31 includes a first RF generator 31a and a second RF generator 31b. The first RF generator 31a is configured to be coupled to the antenna 14 through at least one impedance matching circuit and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to the antenna 14.

The second RF generator 31b is configured to be coupled to at least one bias electrode via at least one impedance matching circuit and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In one embodiment, the bias DC generator 32a is configured to be connected to at least one bias electrode and is configured to generate a bias DC signal. The generated bias DC signal is applied to at least one bias electrode.

In various embodiments, the bias DC signal may be pulsed. In this case, a sequence of the voltage pulses is applied to at least one bias electrode. The voltage pulse may have a pulse waveform of a rectangular, trapezoidal, triangular, or a combination thereof. In one embodiment, a waveform generator for generating the sequence of voltage pulses from the DC signal is connected between the bias DC generator 32a and at least one bias electrode. Therefore, the bias DC generator 32a and the waveform generator constitute a voltage pulse generator. The voltage pulse may have a positive polarity or may have a negative polarity. Further, the sequence of the voltage pulses may include one or a plurality of positive-polarity voltage pulses and one or a plurality of negative-polarity voltage pulses in one cycle. The bias DC generator 32a may be provided in addition to the RF power supply 31, or may be provided instead of the second RF generator 31b.

The antenna 14 includes one or more coils. In one embodiment, the antenna 14 may include an outer coil and an inner coil disposed coaxially. In this case, the RF power supply 31 may be connected to both the outer coil and the inner coil, or may be connected to either the outer coil or the inner coil. In the former case, the same RF generator may be connected to both the outer coil and the inner coil, or separate RF generators may be separately connected to the outer coil and the inner coil.

The exhaust system 40 may be connected to, for example, a gas exhaust port 10e provided in a bottom of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

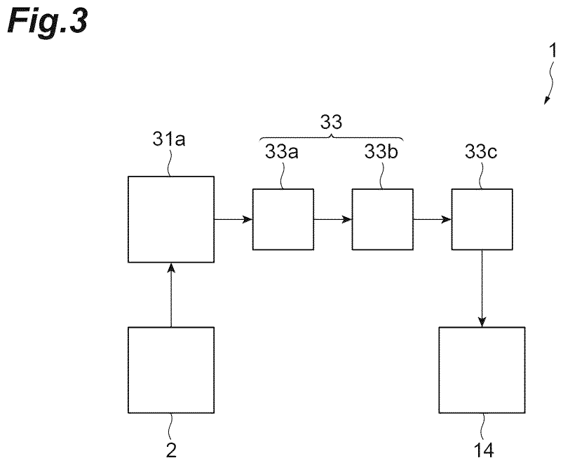

Hereinafter, the first RF generator 31a and the controller 2 will be described with reference to FIG. 3. FIG. 3 is a diagram showing a configuration of a power supply system and a control system in the plasma-processing apparatus according to one exemplary embodiment. The first RF generator 31a is configured to generate an RF signal supplied to generate plasma in the chamber 10, that is, a source RF signal. Details of the source RF signal generated by the first RF generator 31a will be described below. As shown in FIG. 3, the first RF generator 31a is electrically connected to the antenna 14 via a matcher 33c.

The matcher 33c includes an impedance matching circuit having a variable impedance. The matcher 33c is connected between the first RF generator 31a and the antenna 14. The matcher 33c is configured to match the load impedance to the output impedance of the first RF generator 31a. The impedance of the impedance matching circuit of the matcher 33c can be controlled by the controller 2.

The plasma-processing apparatus 1 may further include a plasma state monitor 33. The plasma state monitor 33 is configured to monitor a state of plasma generated in the chamber 10. The plasma state monitor 33 may include a directional coupler 33a and/or a voltage and current sensor 33b.

The directional coupler 33a specifies, for example, a power level of a traveling wave of the source RF signal generated by the first RF generator 31a and a power level of a reflected wave of the source RF signal. The directional coupler 33a may specify a reflectivity of the source RF signal. The reflectivity is specified as a ratio of the power level of the reflected wave to the power level of the traveling wave. The directional coupler 33a can notify the controller 2 of the power level of each of the traveling wave and the reflected wave and the reflectivity.

Each of the power level of the reflected wave and the reflectivity increase in a case where the plasma disappears in the chamber 10. Therefore, the power level of the reflected wave and the reflectivity each represent a state of plasma. The directional coupler 33a may be connected between the first RF generator 31a and the matcher 33c. The directional coupler 33a may be integrated with the first RF generator 31a.

The voltage and current sensor 33b measures the voltage and current of the source RF signal supplied to the antenna 14. The voltage and current sensor 33b may specify the reflection coefficient of the source RF signal from the measured voltage and current. The voltage and current sensor 33b can notify the controller 2 of the specified reflection coefficient. The reflection coefficient increases in a case where the plasma disappears in the chamber 10. Therefore, the reflection coefficient represents the state of plasma.

The source RF signal generated by the first RF generator 31a includes one or both of the first frequency component RF1 and the second frequency component RF2. The first frequency component RF1 is a frequency component for igniting plasma in the chamber 10. The second frequency component RF2 is a frequency component for maintaining the ignited plasma.

The first frequency component RF1 has a first frequency f1. The first frequency f1 may be a resonance frequency of the antenna 14 in a state where the plasma is not ignited in the chamber 10. The first frequency f1 may be a frequency optimized to suppress the reflection of the source RF signal in a state where the plasma is not ignited in the chamber 10. The first frequency f1 may be a frequency set such that the load impedance in a state where the plasma is not ignited in the chamber 10 is matched with the output impedance of the first RF generator 31a. The first frequency f1 may be set based on the design of the plasma-processing apparatus 1 and the species of gas introduced into the chamber 10.

The second frequency component RF2 has a second frequency f2. The second frequency f2 may be a resonance frequency of the antenna 14 in a state where the generated plasma is present in the chamber 10. The second frequency f2 may be a frequency optimized to suppress the reflection of the source RF signal in a state where the generated plasma is present as plasma in the chamber 10. The second frequency f2 may be a frequency set such that the load impedance in a state where the generated plasma is present in the chamber 10 is matched with the output impedance of the first RF generator 31a.

In a first example, the second frequency f2 may be obtained by sweeping the frequency of the source RF signal after the plasma is ignited in the chamber 10. In the first example, the second frequency f2 can be obtained as a frequency at which the degree of reflection is minimized as a result of sweeping the frequency of the source RF signal. The degree of reflection can be evaluated by the power level of the reflected wave, the reflectivity, or the reflection coefficient.

In a second example, the second frequency f2 may be obtained by supplying the source RF signal including a plurality of frequency components to the antenna 14 after the plasma is ignited in the chamber 10. The plurality of frequency components have respective of different frequencies. In the second example, the second frequency f2 can be obtained as a frequency at which the degree of reflection is minimized among the plurality of frequency components. The degree of reflection can be evaluated by the power level of the reflected wave, the reflectivity, or the reflection coefficient.

In a third example, the second frequency f2 may be set from known data. For example, the second frequency f2 may be specified by performing the processing of the first example or the processing of the second example in a frequency range close to the second frequency f2 used in the plasma processing having the condition closest to the current plasma processing condition.

In one embodiment, a difference between the first frequency f1 and the second frequency f2 may be within 5% of the first frequency f1. In one embodiment, the difference between the first frequency f1 and the second frequency f2 may be within 1 MHz.

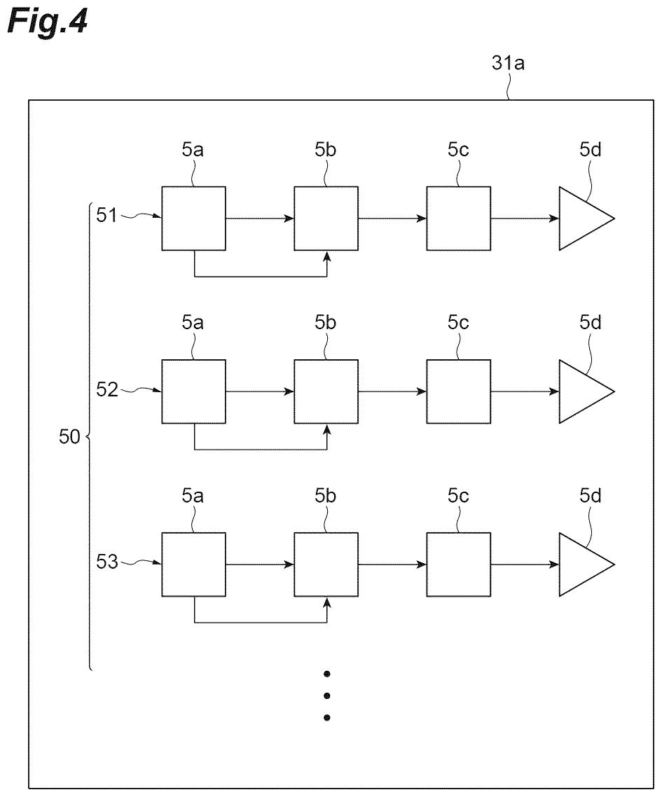

Hereinafter, a configuration example of the first RF generator 31a will be described with reference to FIG. 4. FIG. 4 is a diagram showing a configuration of the first RF generator of the plasma-processing apparatus according to one exemplary embodiment. For example, the first RF generator 31a includes at least one RF generation unit 50. The first RF generator 31a may include a plurality of RF generation units 50. Each of the plurality of RF generation units 50 includes a signal generator 5a, a mixer 5b, a filter 5c, and an amplifier 5d.

The signal generator 5a outputs two signals each having different frequencies to the mixer 5b. The frequencies of the two signals may be designated from the controller 2 to the signal generator 5a. The mixer 5b generates another signal having two frequency components by mixing the two signals output from the signal generator 5a. The frequencies of the two frequency components are the frequencies of the sum and the difference of the frequencies of the two signals output from the signal generator 5a. The filter 5c selectively passes one of two frequency components of the signal generated by the mixer 5b. The signal of the frequency component that has passed through the filter 5c is input to the amplifier 5d. The amplifier 5d amplifies the signal input from the filter 5c to generate one frequency component of the source RF signal. The amplification factor of the amplifier 5d can be designated to the amplifier 5d from the controller 2. Accordingly, the power level of one frequency component of the source RF signal is adjusted.

The first RF generator 31a may include a first RF generation unit 51 and a second RF generation unit 52 as the plurality of RF generation units 50. The first RF generation unit 51 may generate the first frequency component RF1. The second RF generation unit 52 may generate the second frequency component RF2. The source RF signal including one or both of the first frequency component RF1 and the second frequency component RF2 is supplied to the antenna 14 via the directional coupler 33a, the voltage and current sensor 33b, and the matcher 33c. In one embodiment, the first RF generator 31a may further include a third RF generation unit 53 as the plurality of RF generation units 50. Details of the third RF generation unit 53 will be described below.

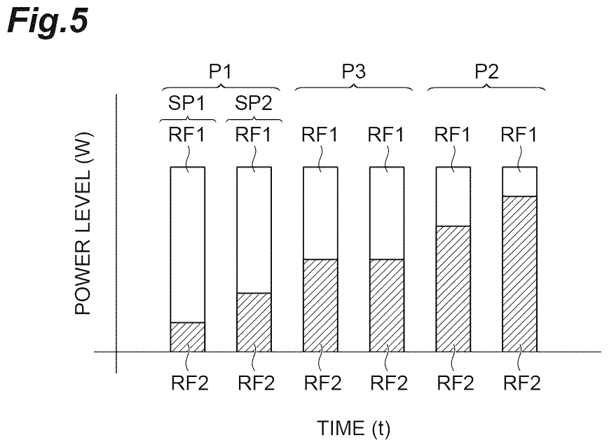

Hereinafter, several embodiments will be described showing a change in time of the plurality of frequency components of the source RF signal generated by the first RF generator 31a. FIG. 5 is a diagram showing a change in time of a plurality of frequency components of the source RF signal (RF signal) generated by the first RF generator in one exemplary embodiment. In FIG. 5, the power level of the source RF signal is constant, but the power level of the source RF signal may vary.

As shown in FIG. 5, in order to ignite plasma in the chamber 10, the controller 2 sets the power level of the first frequency component RF1 of the source RF signal in a first period P1 to a power level greater than the power level of the second frequency component RF2 of the source RF signal. The power level of the second frequency component RF2 in the first period P1 may be greater than zero. In this case, the second frequency component RF2 has a power level greater than zero in the first period P1. The power level of the second frequency component RF2 in the first period P1 may be zero. In this case, the second frequency component RF2 has a zero power level in the first period P1.

In the plasma-processing apparatus 1, the power level of the first frequency component RF1 having the first frequency f1 suitable for igniting plasma is set to a relatively large power level. Therefore, with the plasma-processing apparatus 1, it is possible to ignite plasma at a high speed.

In one embodiment, the first period P1 may include a first sub-period SP1 and a second sub-period SP2. The second sub-period SP2 is a period after the first sub-period SP1. The controller 2 may set the power level of the second frequency component RF2 in the second sub-period SP2 to a power level greater than the power level of the first frequency component RF1 in the first sub-period SP1.

In one embodiment, the power level of the second frequency component RF2 in the first sub-period SP1 may be greater than zero. In this case, the second frequency component RF2 has a power level greater than zero in the first sub-period SP1. The power level of the second frequency component RF2 in the first sub-period SP1 may be zero. In this case, the second frequency component RF2 has a zero power level in the first sub-period SP1.

In order to maintain the ignited plasma, the controller 2 sets the power level of the second frequency component RF2 in the second period P2 to a power level greater than the power level of the first frequency component RF1.

In one embodiment, the power level of the first frequency component RF1 in the second period P2 may be greater than zero. In this case, in the second period P2, the first frequency component RF1 has a power level greater than zero. In one embodiment, in the second period P2, the power level of the first frequency component RF1 may be a minimum power level required for igniting plasma in the chamber 10.

In this case, the first frequency component RF1 has a minimum power level required for igniting the plasma in the chamber 10 in the second period P2. A minimum power level required for igniting plasma in the chamber 10 can be determined in advance. The minimum power level required for igniting the plasma in the chamber 10 is, for example, within a range of 5% to 50% of the maximum value of the power level of the first frequency component RF1 in the first period P1.

In the plasma-processing apparatus 1, the power level of the second frequency component RF2 having the second frequency f2 suitable for maintaining the plasma in a state where the ignited plasma is present is set to a relatively large power level. Therefore, with the plasma-processing apparatus 1, it is possible to efficiently maintain the plasma.

In addition, in the plasma-processing apparatus 1, it is possible to change the source RF signal supplied to the antenna 14 from the source RF signal in the first period P1 to the source RF signal in the second period P2 without a transition period. Therefore, the plasma-processing apparatus 1 can switch between ignition of plasma and maintenance of plasma at a high speed.

In one embodiment, the controller 2 may set the power level of the first frequency component RF1 in a period P3 between the first period P1 and the second period P2 to a power level smaller than the power level of the first frequency component RF1 in the first period P1. The period P3 is a transient period from when the plasma in the chamber 10 is ignited to when the plasma is stably maintained. The power level of the first frequency component RF1 in the period P3 is a power level greater than zero. The controller 2 may set the power level of the second frequency component RF2 in the period P3 to a power level smaller than the power level of the second frequency component RF2 in the second period P2. The power level of the second frequency component RF2 in the period P3 is a power level greater than zero.

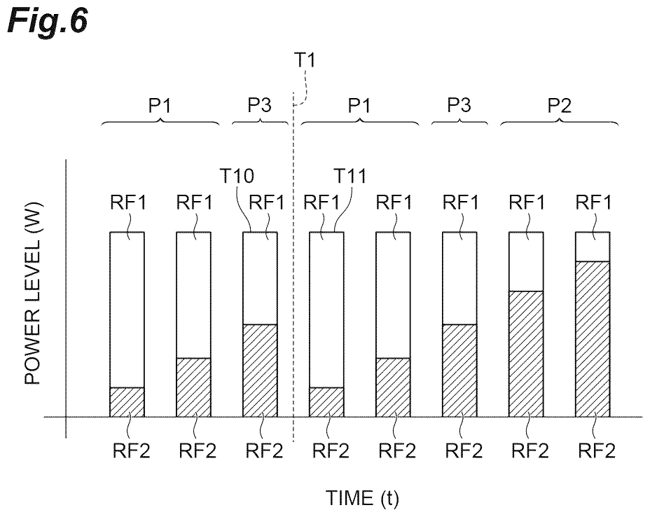

FIG. 6 is a diagram showing a change in time of a plurality of frequency components of the source RF signal generated by the first RF generator in another exemplary embodiment. In one embodiment, the controller 2 may determine the disappearance of the plasma in the chamber 10 from the state of the plasma monitored by the plasma state monitor 33. In a case where it is determined that the plasma has disappeared after the first period P1 from the state of the plasma monitored by the plasma state monitor 33, the controller 2 may control the first RF generator 31a such that the plasma is reignited in the chamber 10. For example, in a case where it is determined that the plasma has disappeared, the controller 2 supplies the source RF signal including the first frequency component RF1.

The controller 2 may set the power level of the first frequency component RF1 of the source RF signal to a power level greater than the power level of the second frequency component RF2 of the source RF signal in order to reignite the plasma. In the example shown in FIG. 6, the controller 2 determines that the plasma has disappeared at a time point T1. At a time point T10 before the time point T1, the power level of the first frequency component RF1 of the source RF signal is less than or equal to the power level of the second frequency component RF2 of the source RF signal. The time point T10 is included in the period P3 between the first period P1 and the second period P2. At a time point T11 after the time point T1, the power level of the first frequency component RFI of the source RF signal is greater than the power level of the second frequency component RF2 of the source RF signal. The time point T11 is included in the first period P1.

As shown in FIG. 6, in the plasma-processing apparatus 1, in a case where it is determined that the plasma has disappeared, the source RF signal including the first frequency component RF1 having the first frequency f1 suitable for igniting the plasma is supplied. Therefore, according to the plasma-processing apparatus 1, it is possible to reignite the plasma at high speed after the plasma has disappeared.

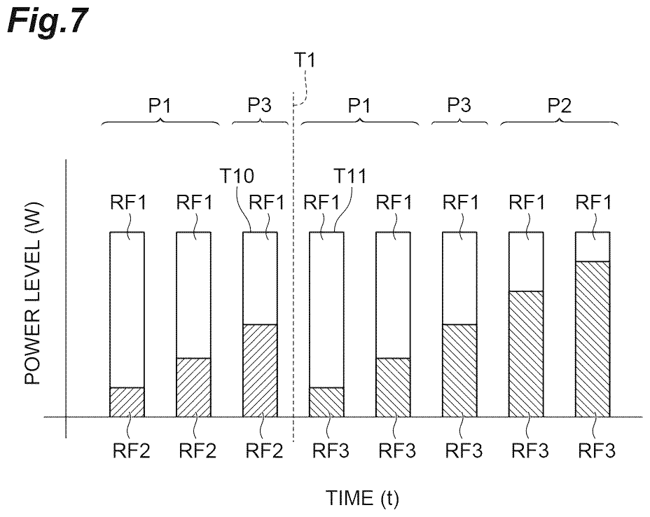

FIG. 7 is a diagram showing a change in time of a plurality of frequency components of a source RF signal generated by the first RF generator in still another exemplary embodiment. In one embodiment, the controller 2 may control the first RF generator 31a to generate the source RF signal including a third frequency component RF3. The third frequency component RF3 is generated by the third RF generation unit 53. The source RF signal including the third frequency component RF3 is supplied to the antenna 14 via the directional coupler 33a, the voltage and current sensor 33b, and the matcher 33c. A frequency f3 of the third frequency component RF3 is different from the first frequency f1 and the second frequency f2. The frequency f3, like the second frequency f2, is a frequency suitable for maintaining the ignited plasma. The frequency f3 may be higher than the first frequency f1 and lower than the second frequency f2.

In one embodiment, in a case where it is determined that the plasma has disappeared after the first period P1 from the state of the plasma monitored by the plasma state monitor 33, the controller 2 may reignite the plasma in the chamber 10. The controller 2 may control the first RF generator 31a to supply the source RF signal including the third frequency component RF3 after reigniting the plasma in the chamber 10.

In a case where it is determined that the plasma has disappeared after the first period P1, the controller 2 may control the first RF generator 31a to supply the source RF signal including the third frequency component RF3 instead of the second frequency component RF2. In the example shown in FIG. 7, the controller 2 determines that the plasma has disappeared at the time point T1 after the first period P1. At the time point T10 before the time point T1, the source RF signal includes the first frequency component RF1 and the second frequency component RF2. At the time point T11 after the time point T1, the source RF signal includes the third frequency component RF3 instead of the second frequency component RF2.

The time point T11 is included in the first period P1. In order to ignite plasma in the chamber 10, the controller 2 may set the power level of the first frequency component RF1 of the source RF signal in a first period P1 to a power level greater than the power level of the third frequency component RF3 of the source RF signal. In the example shown in FIG. 7, the power level of the third frequency component RF3 in the first period P1 is greater than zero. The controller 2 may set the power level of the third frequency component RF3 in the second period P2 to a power level greater than the power level of the first frequency component RF1 in order to maintain the ignited plasma after reigniting the plasma in the chamber 10.

In the plasma-processing apparatus 1, the source RF signal including the third frequency component RF3 is supplied after the plasma has disappeared. The third frequency component RF3 has a frequency different from the second frequency f2 of the second frequency component, which is set to a relatively large power level when the plasma disappears. Therefore, in the plasma-processing apparatus 1, the plasma is easily reignited after the plasma has disappeared.

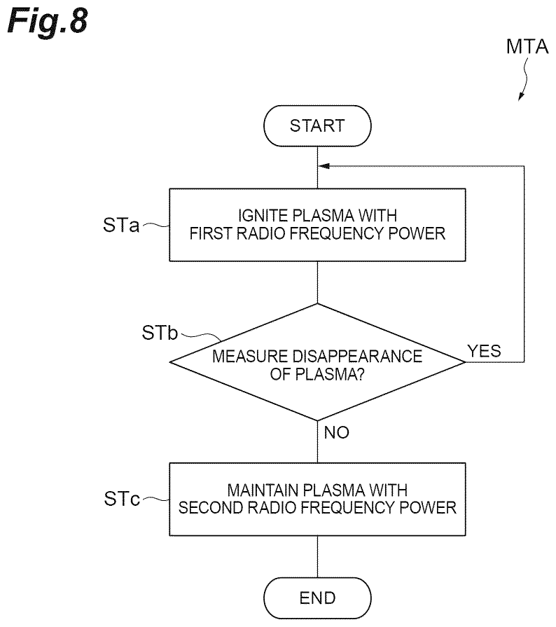

Hereinafter, a plasma-processing method according to one exemplary embodiment will be described with reference to FIG. 8. FIG. 8 is a flowchart of the plasma-processing method according to one exemplary embodiment. The plasma-processing method shown in FIG. 8 (hereinafter, referred to as a “MTA method”) can be performed in a state where a substrate is placed on the substrate support 11. In order to perform each step of the method MTA, each unit of the plasma-processing apparatus 1 can be controlled by the controller 2.

The method MTA starts in Step STa. In Step STa, in order to ignite plasma in the chamber 10, the source RF signal including the first frequency component RF1 is supplied from the first RF generator 31a to the antenna 14 in the first period P1. In Step STa, the power level of the first frequency component RF1 of the source RF signal is greater than the power level of the second frequency component RF2 of the source RF signal.

In one embodiment, the method MTA may include Step STb. Step STb is performed after Step STa. In Step STb, it is determined whether or not the plasma has disappeared after the first period P1 from the state of the plasma monitored by the plasma state monitor 33. In a case where it is determined that the plasma has disappeared, the source RF signal including the first frequency component RF1 is supplied from the first RF generator 31a to the antenna 14. In a case where it is determined that the plasma has disappeared, Step STa may be performed again.

In Step STc, in order to maintain the ignited plasma, the source RF signal having the second frequency component RF2 is supplied from the first RF generator 31a to the antenna 14 in the second period P2. As described above, in the second period P2, the power level of the second frequency component RF2 of the source RF signal is greater than the power level of the first frequency component RF1 of the source RF signal.

In the example of FIG. 8, Step STb is performed after Step STa and before Step STc. However, Step STb may be performed in parallel with Step STc.

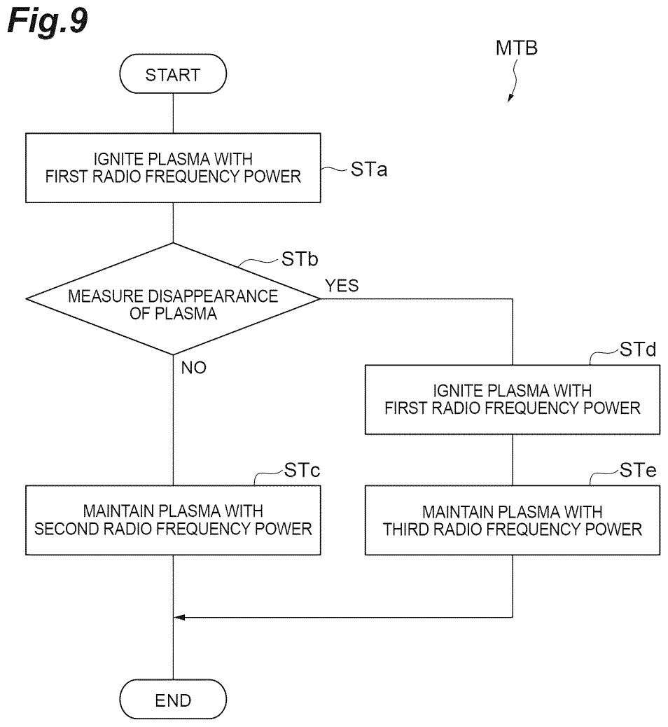

Hereinafter, a plasma-processing method according to another exemplary embodiment will be described with reference to FIG. 9. FIG. 9 is a flowchart of a plasma-processing method according to another exemplary embodiment. The plasma-processing method shown in FIG. 9 (hereinafter, referred to as a “method MTB”) may be performed instead of the method MTA. Hereinafter, the method MTB will be described from the viewpoint of differences from the method MTA.

The method MTB includes Step STd and Step STe. Step STd and Step STe are performed in a case where it is determined that the plasma has disappeared in Step STb. In Step STe, the plasma is reignited in the chamber 10. Step STe is performed after Step STd. In Step STe, the source RF signal including the third frequency component RF3 is supplied.

In Step STd, the source RF signal including the first frequency component RF1 is supplied in order to ignite the plasma in the chamber 10. The source RF signal may include the third frequency component RF3 instead of the second frequency component RF2. In Step STd, the power level of the first frequency component RF1 of the source RF signal is greater than the power level of the third frequency component RF3 of the source RF signal. In one embodiment, the power level of the third frequency component RF3 of the source RF signal in Step STd may be greater than zero.

In Step STe, in order to maintain the reignited plasma, the source RF signal having the third frequency component RF3 is supplied from the first RF generator 31a to the antenna 14. In Step STe, the power level of the third frequency component RF3 of the source RF signal may be greater than the power level of the first frequency component RF1 of the source RF signal.

In one embodiment, the power level of the first frequency component RF1 in Step STe may be greater than zero. In one embodiment, the power level of the first frequency component RF1 in Step STe may be a minimum power level required for igniting the plasma in the chamber 10.

Although the various exemplary embodiments have been described above, various additions, omissions, substitutions, and changes may be made without being limited to the exemplary embodiments described above. In addition, other embodiments can be formed by combining elements in different embodiments.

The plasma-processing apparatus 1 may include an optical sensor. The optical sensor is disposed in the chamber 10. The optical sensor is included in the plasma state monitor 33. The optical sensor monitors emission intensity in the chamber 10. The emission intensity indicates a state of plasma. The plasma state monitor 33 notifies the controller 2 of the emission intensity. The controller 2 determines ignition of plasma and disappearance of plasma from the emission intensity in the chamber 10.

In addition, the first RF generator 31a may include a single RF generation unit 50. The first RF generator 31a may generate a source RF signal including only the first frequency component RF1 in the first period P1 by using the single RF generation unit 50. In this case, the power level of the second frequency component RF2 in the first period P1 is zero. The first RF generator 31a may generate a source RF signal including only the second frequency component RF2 in the second period P2 by using the single RF generation unit 50. In this case, the power level of the first frequency component RF1 in the second period P2 is zero.

Here, the various exemplary embodiments included in the present disclosure are described in [E1] to [E16] below.

[E1] A plasma-processing apparatus including: a chamber; a substrate support in the chamber; an antenna above the substrate support; an RF generator that is electrically connected to the antenna and is configured to generate an RF signal including one or both of a first frequency component for igniting plasma in the chamber and a second frequency component for maintaining the ignited plasma, the first frequency component having a first frequency and the second frequency component having a second frequency which is a matching frequency different from the first frequency; and a controller configured to control the RF generator to set, in a first period, a power level of the first frequency component of the RF signal to a power level greater than a power level of the second frequency component of the RF signal in order to ignite the plasma in the chamber, and set, in a second period, the power level of the second frequency component of the RF signal to a power level greater than the power level of the first frequency component of the RF signal in order to maintain the ignited plasma.

[E2] A plasma-processing apparatus including: a chamber; a substrate support in the chamber; an RF generator configured to generate an RF signal including one or both of a first frequency component for igniting plasma in the chamber and a second frequency component for maintaining the ignited plasma, the first frequency component having a first frequency and the second frequency component having a second frequency which is a matching frequency different from the first frequency; and a controller configured to control the RF generator to set, in a first period, a power level of the first frequency component of the RF signal to a power level greater than a power level of the second frequency component of the RF signal in order to ignite the plasma in the chamber, and set, in a second period, the power level of the second frequency component of the RF signal to a power level greater than the power level of the first frequency component of the RF signal in order to maintain the ignited plasma.

[E3] The plasma-processing apparatus according to E1 or E2, in which the second frequency component has a power level greater than zero in the first period.

[E4] The plasma-processing apparatus according to any one of E1 to E3, in which the first frequency component has a power level greater than zero in the second period.

[E5] The plasma-processing apparatus according to any one of E1 to E4, in which the first frequency component has a minimum power level required for igniting the plasma in the chamber in the second period.

[E6] The plasma-processing apparatus according to any one of E1 to E5, in the first period includes a first sub-period and a second sub-period after the first sub-period, and the controller is configured to control the RF generator to set a power level of the second frequency component in the second sub-period to a power level greater than a power level of the second frequency component in the first sub-period.

[E7] The plasma-processing apparatus according to any one of E1 to E6, in which the second frequency component has a power level greater than zero in the first sub-period.

[E8] The plasma-processing apparatus according to any one of E1 to E6, in which the second frequency component has a zero power level in the first sub-period.

[E9] The plasma-processing apparatus according to any one of E1 to E8, in which a difference between the first frequency and the second frequency is within 5% of the first frequency.

[E10] The plasma-processing apparatus according to any one of E1 to E9, in which a difference between the first frequency and the second frequency is within 1 MHz.

[E11] The plasma-processing apparatus according to any one of E1 to E10, in which the controller is configured to control the RF generator to set a power level of the first frequency component in a period between the first period and the second period to a power level greater than zero and smaller than the power level of the first frequency component in the first period, and set a power level of the second frequency component in the period between the first period and the second period to a power level greater than zero and smaller than the power level of the second frequency component in the second period.

[E12] The plasma-processing apparatus according to any one of E1 to E11, further including: a plasma state monitor configured to monitor a state of the plasma generated in the chamber, in which the controller is configured to control the RF generator to supply the RF signal including the first frequency component in order to reignite the plasma in the chamber in a case of determining that the plasma has disappeared after the first period based on the state of the plasma monitored by the plasma state monitor.

[E13] The plasma-processing apparatus according to E12, in which the controller is configured to reignite the plasma in the chamber and control the RF generator to supply the RF signal including a third frequency component, in a case where it is determined that the plasma has disappeared after the first period based on the state of the plasma monitored by the plasma state monitor, and a frequency of the third frequency component is different from the first frequency and the second frequency.

[E14] A plasma-processing method including: supplying, in a first period, an RF signal including a first frequency component from an RF generator to an antenna that is above a chamber in a plasma-processing apparatus in order to ignite plasma in the chamber; and supplying, in a second period, the RF signal including a second frequency component from the RF generator to the antenna in order to maintain the ignited plasma, in which the first frequency component has a first frequency and the second frequency component has a second frequency which is a matching frequency different from the first frequency, in the supplying of the RF signal including the first frequency, a power level of the first frequency component of the RF signal is greater than a power level of the second frequency component of the RF signal, and in the supplying of the RF signal including the second frequency, the power level of the second frequency component of the RF signal is greater than the power level of the first frequency component of the RF signal.

[E15] The plasma-processing method according to E14, further including: supplying the RF signal including the first frequency component to reignite the plasma in the chamber in a case of determining that the plasma has disappeared after the first period based on a state of the plasma monitored by a plasma state monitor.

[E16] The plasma-processing method according to E15, further including: reigniting the plasma in the chamber and supplying the RF signal including a third frequency component in a case of determining that the plasma has disappeared after the first period based on the state of the plasma monitored by the plasma state monitor, in which a frequency of the third frequency component is different from the first frequency and the second frequency.

From the foregoing description, it will be understood that various embodiments of the present disclosure have been described in the present specification for purposes of illustration, and that various modifications may be made without departing from the scope and spirit of the present disclosure. Accordingly, the various embodiments disclosed in the present specification are not intended to be limiting, with the true scope and spirit being indicated by the following claims.

What is claimed is:

1. A plasma-processing apparatus comprising:
a chamber;
a substrate support in the chamber;
an antenna above the substrate support;
an RF generator that is electrically connected to the antenna and is configured to generate an RF signal including one or both of a first frequency component for igniting plasma in the chamber and a second frequency component for maintaining the ignited plasma, the first frequency component having a first frequency and the second frequency component having a second frequency which is a matching frequency different from the first frequency; and
a controller configured to control the RF generator to
set, in a first period, a power level of the first frequency component of the RF signal to a power level greater than a power level of the second frequency component of the RF signal in order to ignite the plasma in the chamber, and
set, in a second period, the power level of the second frequency component of the RF signal to a power level greater than the power level of the first frequency component of the RF signal in order to maintain the ignited plasma.

2. A plasma-processing apparatus including:
a chamber;
a substrate support in the chamber;
an RF generator configured to generate an RF signal including one or both of a first frequency component for igniting plasma in the chamber and a second frequency component for maintaining the ignited plasma, the first frequency component having a first frequency and the second frequency component having a second frequency which is a matching frequency different from the first frequency; and
a controller configured to control the RF generator to
set, in a first period, a power level of the first frequency component of the RF signal to a power level greater than a power level of the second frequency component of the RF signal in order to ignite the plasma in the chamber, and
set, in a second period, the power level of the second frequency component of the RF signal to a power level greater than the power level of the first frequency component of the RF signal in order to maintain the ignited plasma.

3. The plasma-processing apparatus according to claim 2, wherein
the second frequency component has a power level greater than zero in the first period.

4. The plasma-processing apparatus according to claim 2, wherein
the first frequency component has a power level greater than zero in the second period.

5. The plasma-processing apparatus according to claim 2, wherein
the first frequency component has a minimum power level required for igniting the plasma in the chamber in the second period.

6. The plasma-processing apparatus according to claim 5, wherein
the first period includes
a first sub-period; and
a second sub-period after the first sub-period, and
the controller is configured to control the RF generator to set a power level of the second frequency component in the second sub-period to a power level greater than a power level of the second frequency component in the first sub-period.

7. The plasma-processing apparatus according to claim 6, wherein
the second frequency component has a power level greater than zero in the first sub-period.

8. The plasma-processing apparatus according to claim 6, wherein
the second frequency component has a zero power level in the first sub-period.

9. The plasma-processing apparatus according to claim 2, wherein
a difference between the first frequency and the second frequency is within 5% of the first frequency.

10. The plasma-processing apparatus according to claim 2, wherein
a difference between the first frequency and the second frequency is within 1 MHz.

11. The plasma-processing apparatus according to claim 2, wherein
the controller is configured to
control the RF generator to set a power level of the first frequency component in a period between the first period and the second period to a power level greater than zero and smaller than the power level of the first frequency component in the first period, and
set a power level of the second frequency component in the period between the first period and the second period to a power level greater than zero and smaller than the power level of the second frequency component in the second period.

12. The plasma-processing apparatus according to claim 2, further comprising:
a plasma state monitor configured to monitor a state of the plasma generated in the chamber,
wherein the controller is configured to control the RF generator to supply the RF signal including the first frequency component in order to reignite the plasma in the chamber in a case where it is determined that the plasma has disappeared after the first period based on the state of the plasma monitored by the plasma state monitor.

13. The plasma-processing apparatus according to claim 12, wherein
the controller is configured to reignite the plasma in the chamber and control the RF generator to supply the RF signal including a third frequency component, in a case of determining that the plasma has disappeared after the first period based on the state of the plasma monitored by the plasma state monitor, and
a frequency of the third frequency component is different from the first frequency and the second frequency.

14. A plasma-processing method comprising:
supplying, in a first period, an RF signal including a first frequency component from an RF generator to an antenna that is above a chamber in a plasma-processing apparatus in order to ignite plasma in the chamber; and
supplying, in a second period, the RF signal including a second frequency component from the RF generator to the antenna in order to maintain the ignited plasma,
wherein the first frequency component has a first frequency and the second frequency component has a second frequency which is a matching frequency different from the first frequency,
in the supplying of the RF signal including the first frequency, a power level of the first frequency component of the RF signal is greater than a power level of the second frequency component of the RF signal, and
in the supplying of the RF signal including the second frequency, the power level of the second frequency component of the RF signal is greater than the power level of the first frequency component of the RF signal.

15. The plasma-processing method according to claim 14, further comprising:
supplying the RF signal including the first frequency component to reignite the plasma in the chamber in a case of determining that the plasma has disappeared after the first period based on a state of the plasma monitored by a plasma state monitor.

16. The plasma-processing method according to claim 15, further comprising:
reigniting the plasma in the chamber and supplying the RF signal including a third frequency component in a case of determining that the plasma has disappeared after the first period based on the state of the plasma monitored by the plasma state monitor,
wherein a frequency of the third frequency component is different from the first frequency and the second frequency.
